(19) United States
(12) Patent Application Publication
(10) Pub. No.: US 2020/0243706 A1
(43) Pub. Date: Jul. 30, 2020

(54) SOLAR CELL MODULE

(71) Applicant: Panasonic Corporation, Osaka (JP)

(72) Inventors: Yuya Nakamura, Osaka (JP); Yoshinobu Momonoi, Hyogo (JP)

(73) Assignee: Panasonic Corporation, Kadoma-shi, Osaka (JP)

(21) Appl. No.: 16/774,238

(22) Filed: Jan. 28, 2020

(30) Foreign Application Priority Data
Jan. 30, 2019 (JP) 2019-014458

(51) Int. Cl. H01L 31/05; H01L 31/048

(52) U.S. Cl. CPC H01L 31/0504; H01L 31/0481; H01L 31/0488

(57) ABSTRACT

A solar cell module according to an example of an embodiment of this disclosure includes a plurality of solar cells and a wiring member configured to connect, among the plurality of solar cells, a first solar cell and a second solar cell which are adjacent to each other. The solar cell module further includes a first protective base, a second protective base, a first encapsulant disposed between the first protective base and the plurality of solar cells, and a second encapsulant disposed between the second protective base and the plurality of solar cells. The first protective base is a translucent glass base. The first encapsulant has a rate of stress relaxation in a range of 0.18˜0.52 at a temperature of 90° C.

### CROSS REFERENCE TO RELATED APPLICATION

This application claims priority to Japanese Patent Application No. 2019-014458 filed on Jan. 30, 2019, which is incorporated herein by reference in its entirety including the specification, claims, drawings, and abstract.

### TECHNICAL FIELD

The present disclosure relates to a solar cell module.

### BACKGROUND

A solar cell module includes strings of a plurality of solar cells formed by connecting the plurality of solar cells through wiring members, two protective bases configured to hold the strings between the two protective bases, and an encapsulant disposed between the protective bases and configured to seal each of the solar cells (see, for example, Japanese Unexamined Patent Application Publication No. 2016-143680). The encapsulant is brought into close contact with each of the protective bases and the solar cells to constrain movement of the solar cells, and has a function of protecting the solar cells from moisture and the like. The above-described Patent Application Publication No. 2016-143680 describes that a resin containing a polyolefin as a principle component is used for an encapsulant.

The temperature of a solar cell module varies greatly depending on the environment around the solar cell module. For this reason, it is required that the solar cell module have a superior tolerance to thermal cycles in which the temperature changes between a low temperature and a high temperature. In connection with the thermal cycles, a particularly problematic issue is occurrence of a break in a wiring member for connecting solar cells adjacent to each other. Specifically, an interval between the solar cells (an inter-cell distance) is changed through the thermal cycles, which may cause the wiring member to be subjected to a great load. This raises a possibility that the wiring member will be broken.

### SUMMARY

In an aspect of this disclosure, a solar cell module includes a plurality of solar cells, a wiring member configured to connect, among the plurality of solar cells, a first solar cell and a second solar cell which are adjacent to each other, a first protective base disposed on a light receiving surface side of the plurality of solar cells, a second protective base disposed on a rear surface side of the plurality of solar cells, a first encapsulant disposed between the first protective base and the plurality of solar cells, and a second encapsulant disposed between the second protective base and the plurality of solar cells. In the solar cell module, the first protective base is a translucent glass base, and a rate of stress relaxation of the first protective base at a temperature of 90° C. is in a range of 0.18-0.52.

In the solar cell module according to another aspect of this disclosure, Young's modulus of the first encapsulant is in a range of 14 MPa 54 MPa.

In the solar cell module according to a further aspect of this disclosure, a value of (Young's modulus)×(thickness) of the second protective base is equal to or greater than 0.1 GPa·mm, while a linear expansion coefficient of the second protective base is equal to or greater than 40 ppm/° C., and is also confined within a range from a lower limit which is set to a value (α1) determined by the following Equation 1 to an upper limit which is set to a value (α2) determined by the following Equation 2

α1 (ppm/° C.)=583×E²−623×E+176 Equation 1:

α2 (ppm/° C.)=500×E²−590×E+190 Equation 2:

In the above equations, reference letter E represents the value (GPa·mm) of (Young's modulus)×(thickness) of the second protective base.

In the solar cell module according to one aspect of this disclosure, it is possible to significantly suppress the occurrence of a break in the wiring member resulting from thermal cycles.

### BRIEF DESCRIPTION OF DRAWINGS

The figures depict one or more implementations in accordance with the present teaching, by way of example only, not by way of limitations. In the figures, like reference numerals refer to the same or similar elements.

FIG. 1 is a plan view showing a part of a solar cell module according to one example of an embodiment;

FIG. 2 is a diagram showing a part of a cross section view taken along a line AA indicated in FIG. 1;

FIG. 3A is a diagram showing a relationship between the number of thermal cycles and an amount of change in an inter-cell distance identified while changing a rate of stress relaxation of a first encapsulant;

FIG. 3B is a diagram showing the relationship between the number of thermal cycles and the amount of change in the inter-cell distance identified while changing the rate of stress relaxation of the first encapsulant;

FIG. 4 is a diagram for explaining a simulation model of the solar cell module;

FIG. 5A is a diagram showing a relationship between the number of thermal cycles and the amount of change in the inter-cell distance identified while changing Young's modulus of the first encapsulant;

FIG. 5B is a diagram showing the relationship between the number of thermnal cycles and the amount of change in the inter-cell distance identified while changing Young's modulus of the first encapsulant; and.

FIG. 6 is a diagram showing suitable ranges of the Young's modulus and the linear expansion coefficient of a second protective base.

### DESCRIPTION OF EMBODIMENTS

Hereinafter, one example of a solar cell module according an embodiment of the present disclosure will be described in detail with reference to the drawings. The drawings referred to in the following description of the embodiment are schematically illustrated, and dimensional ratios and other geometrical features of components illustrated in the drawings should be understood in consideration with the description below. As used herein, the expression “a numerical value (A)˜a numerical value (B)” is intended to denote values “equal to or greater than the numerical value (A) and equal to or smaller than the numerical value (B)” unless otherwise specified in the specification.

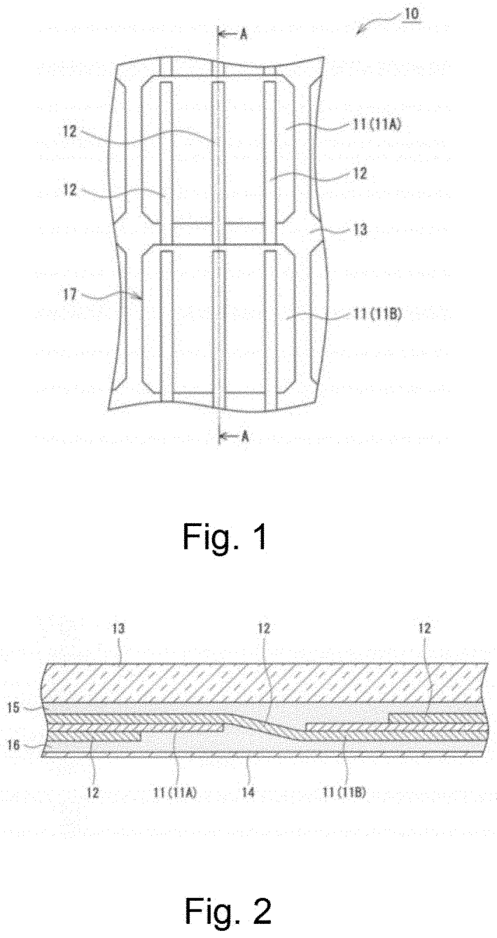

FIG. 1 is a plan view showing a part of a solar cell module 10 in one example of an embodiment, and FIG. 2 is a diagram showing a part of a cross section view taken along a line AA indicated in FIG. 1. As illustrated in FIGS. 1 and 2, the solar cell module 10 includes a plurality of solar cells 11, wiring members 12, a first protective base 13, and a second protective base 14. The wiring member 12 connects, among the plurality of solar cells 11, a first solar cell 11A and a second solar cell IIB which are adjacent to each other. The first protective base 13 is disposed on a light receiving surface side of the plurality of solar cells 11, while the second protective base 14 is disposed on a rear surface side of the plurality of solar cells 11. The solar cell module 10 has, for example, a rectangular shape in plan view, although the shape of the solar cell module 10 may be changed as appropriate, and may be a square, a pentagon, or other shapes in plan view.

Here, a “light receiving surface” of the solar cells 11 denotes a surface upon which light is mainly incident, while a “rear surface” of the solar cells 11 denotes a surface opposite to the light receiving, surface. In the light incident onto the solar cells 11, more than 50% of the light, for example, 80% or more of the light, or 90% or more of the light, is incident from the light receiving surface side. The terms of the light receiving surface and the rear surface are also used for representing surfaces of the solar cell module 10, a below-described photoelectric converter, and other components.

The solar cell module 10 further includes a first encapsulant 15 disposed between the first protective base 13 and the plurality of solar cells 11, and a second encapsulant 16 disposed between the second protective base 14 and the plurality of solar cells 11. The first protective base 13 may be a translucent glass base, while the second protective base 14 may be a base predominantly composed of a resin, which will be described in detail further below. In the solar cell module 10, when the first encapsulant 15 has a rate of stress relaxation in a range of 0.18-0.52 at a temperature of 90° C., occurrence of a break in the wiring member 12 resulting from thermal cycles can be significantly suppressed.

Each of the solar cells 11 includes the photoelectric converter which is configured to generate a carrier upon receipt of sunlight, and a collector electrode which is disposed on the photoelectric converter and configured to collect the carrier. The photoelectric converter illustrated in FIG. 1 has the shape of substantially a square with four corners being obliquely cut in plan view. As an example, the photoelectric converter may include a semiconductor substrate composed of crystalline silicon (Si), gallium arsenide (GaAs), indium phosphor (InP), or the like, an amorphous semiconductor layer formed on the semiconductor layer, and a transparent conductive layer formed on the amorphous semiconductor layer.

The collector electrode includes a light receiving surface electrode formed on the light receiving surface of the photoelectric converter, and a rear surface electrode formed on the rear surface of the photoelectric converter. In this case, one of the light receiving, surface electrode and the rear surface electrode functions as an n-side electrode, and the other of light receiving surface electrode and the rear surface electrode functions as a p-side electrode. It should be noted that in the solar cell 11, both the n-side and p-side electrodes may be arranged only on the rear surface side of the photoelectric converter. In general, because the rear surface electrode is designed to have a greater area than that of the light receiving surface electrode, the rear surface of the solar cell 11 may be considered as a surface where the area of the collector electrode is greater, or a surface where the collector electrode is formed. This embodiment will be described with respect to the collector electrode which includes, as the collector electrode, both the light receiving surface electrode and the rear surface electrode.

The collector electrode may include a plurality of finger electrodes. However, the rear surface electrode in the collector electrode may be formed as an electrode which covers substantially the entire area of the rear surface of the photoelectric converter. The plurality of finger electrodes are thin linear electrodes which are formed substantially parallel to each other. The collector electrode may further include a bus bar electrode which has a greater width than the width of the finger electrode and is arranged substantially orthogonally to the finger electrodes. In a case where the bus bar electrode is arranged, the wiring member 12 is disposed on the bus bar electrode along the bus bar electrode.

The plurality of solar cells 11 are sandwiched between the first protective base 13 and the second protective base 14, and sealed by the first encapsulant 15 and the second encapsulant 16 which are composed of resin filled in space between the first and second protective bases 13 and 14. The plurality of solar cells 11 are arranged substantially on the same plane along the surfaces of the first and second protective bases 13 and 14. It should be noted that the protective bases are not limited to planar bases, and may be curved bases. Mutually adjacent solar cells 11 are serially connected by the wiring member 12 so as to form a string 17 of the solar cells 11. The wiring member 12 is typically referred to as an interconnector or a tab.

The wiring member 12 is a wiring material in the shape of, for example, a rectangle, and is predominantly composed of a metal, such as copper (Cu) or aluminum (Al). The wiring member 12 may include a plated layer which contains, as a principle component, silver (Ag), nickel (Ni), or a low melting point alloy used as solder. In general, the wiring member 12 is arranged in such a manner that two or more wiring members 12 are attached to each of the light receiving surface and the rear surface of a single solar cell 11. In the example shown in FIG. 1, three wiring members 12 on the light receiving surface and three wiring members 12 on the rear surface, i.e. six wiring members 12 in total, are attached to the single solar cell 11.

The wiring members 12 are placed along a longitudinal direction of the string 17, and extend from an end of the solar cell 11A to an end of the solar cell 11B that is located on the other side of an end of the solar cell 11B opposed to the solar cell 11A. The length of the wiring members 12 is slightly shorter than a total length of two solar cells 11 and the inter-cell distance. Each of the wiring members 12 is bent to a thickness direction of the solar cell module 10 between the solar cells 11A and 11B and attached to both the light receiving surface of the solar cell I1A and the rear surface of the solar cell 11B by means of a resin adhesive agent or soldering. Then, the wiring member 12 is electrically connected to the collector electrode of the solar cells 11. The resin adhesive agent may contain a conductive filler. A portion of the wiring member 12 located in an inter-cell space is defined as a bent portion.

The solar cell module 10 typically includes two or more strings 17 in which the plurality of solar cells 11 connected in series by the wiring members 12 are arranged in a line. On both longitudinal ends of each of the strings 17, a crossover wire is arranged to electrically connect adjacent strings 17. The solar cell module 10 may include a frame which is attached along peripheral edges of the first protective base 13 and the second protective base 14. The frame functions to protect the peripheral edges of the protective bases, and is used for attaching the solar cell module 10 to a roof or the like. Alternatively, the solar cell module 10 may be a so-called frameless module which has no frame.

The solar cell module 10 has multilayer structure in which the first protective base 13, the first encapsulant 15, the strings 17 of the solar cells 11, the second encapsulant 16, and the second protective base 14 are stacked in that order from the light receiving surface side. It should be noted that the solar cell module 10 may include other components between the first protective base 13 and the second protective base 14 in place of the encapsulants, as long as the components do not impair the object of this disclosure.

Hereinafter, the first protective base 13, the second protective base 14, the first encapsulant 15, and the second encapsulant 16 will be described. In particular, the first encapsulant 15 will be explained in detail.

The first protective base 13 covers all over the strings 17 to protect the solar cells 11 against external impact forces, moisture, and the like. The translucent glass base (glass substrate) is used for the first protective base 13. It is desirable for the first protective base 13 to have a high total luminous transmittance that is, for example, in a range of 80%-100%, or 85%-95%. The total luminous transmittance is measured based on a method according, to Japan Industrial Standard (JIS) K7361-1 (Plastics—Determination of the total luminous transmittance of transparent materials Part 1: Single beam instrument).

For the second protective base 14, a translucent base similar to the first protective base 13 may be used, or an opaque base may be used in a case where the solar cell module 10 is not intended to receive light incident from the rear surface side thereof. The total luminous transmittance of the second protective base 14 is not limited to any values, and may even be 0%. A glass base or a metallic base may be used for the second protective base 14, although a resin base may preferably be used for the second protective base 14 in light of reduction in weight of the solar cell module 10. In this embodiment, a resin base (a resin film) having a thickness smaller than that of the first protective base 13 is employed as the second protective base 14.

In the solar cell module 10, stiffness of the first protective base 13 is higher than stiffness of the second protective base 14. The stiffness (N·m²) of the base is obtained by calculating a value of (Young's modulus) x (second moment of area). For the first or second protective base 13 or 14 having a plate shape in cross section, for example, the second moment of area (I) is obtained by an equation of I=[width b (in)×thickness h (mm)]³/12. The Young's modulus of the first protective base 13 is greater than the Young's modulus of the second protective base 14, while a thermal expansion coefficient of the first protective base 13 is smaller than a thermal expansion coefficient of the second protective base 14. The Young's modulus (E) is measured for each component based on JIS K7161-1. On the other and, the linear expansion coefficient is measured based on JIS K7197.

The first encapsulant 15 and the second encapsulant 16 are disposed, as described above, between the first protective base 13 and the second protective base 14, and composed of resin for sealing the strings 17 of the solar cells 11. The first encapsulant 15 and the second encapsulant 16 are brought into intimate contact with the solar cells 11 to constrain the solar cells 11 from moving, and to seal the solar cells 11 against oxygen, water vapor, and other materials. In particular, when a moisture content within the module is increased, deterioration in performance, such as decrease in output, is accelerated. To prevent this, it is preferable that a resin having a lower degree of water vapor permeability and a lower rate of water absorption is used for the encapsulant.

There is no specific limitation to the thickness of the first encapsulant 15, while the thickness is preferably within a range of 0.1 mm-2 mm in light of properties of the solar cells 11, such as a sealing property and a light transmitting property. The thickness of the second encapsulant 16 is similar to the thickness of the first encapsulant 15, for example. A suitable range of the thickness will be described in detail further below. The first encapsulant 15 preferably has a high total luminous transmittance, for example, in a range of 80%-100% or 85%-95%. On the other hand, the total luminous transmittance of the second encapsulant 16 is not limited to a specific range. When it is not intended to receive light incident from the rear surface side of the solar cell module 10, the second encapsulant 16 may contain a coloring material, such as a white pigment or a black pigment, and may have a total luminous transmittance of 0%.

While the first encapsulant 15 and second encapsulant 16 may be formed of the same resin, it may be preferable that the first encapsulant 15 and the second encapsulant 16 are formed of different resins. In the solar cell module 10, because the glass base is used for the first protective base 13 while the resin base is used for the second protective base 14, moisture is apt to infiltrate into the solar cell module 10 from a second protective base 14 side. Here, it is not possible for the infiltrated moisture to escape from a first protective base 13 side. For this reason, it is preferable that a resin having a lower water absorption rate and a superior hydrophobic property is used, in particular, for the first encapsulant 15. For example, a polyolefin may be used for the first encapsulant 15 and an ethylene/vinyl acetate (EVA) copolymer may be used for the second encapsulant 16.

Because the solar cell module 10 is assumed to be used in environments having various temperatures from a low temperature, such as −40° C., to a high temperature, such as 90° C., it is desirable for the solar cell module 10 to have a high tolerance to thermal cycles. As described above, a particularly problematic issue associated with the thermal cycles in the solar cell module 10 is a break in the wiring member 12. A repetition of thermal cycles between low temperatures and high temperatures will cause a change in the inter-cell distance. The change in the inter-cell distance exerts a high load on the wiring member 12, and accordingly raises a possibility that the wiring member 12 will be broken. Especially when the polyolefin is used for the first encapsulant 15, the wiring member 12 is more apt to be broken through the thermal cycles.

The present inventors have diligently studied the influence of the thermal cycles of the solar cell module through analysis of stress acting on the encapsulant and effects exerted by the stress on the inter-cell distance. As a result of the study, the present inventors have found that a rate of stress relaxation of the first encapsulant 15 is an extremely important factor for preventing a break in the wiring member 12. When the thermal cycle is repeated, a combination of compressive stress and tensile stress acts on the first encapsulant 15 held between the first protective base 13 and the solar cells 11, both of which are of high stiffness, in a complicated way, at and around inter-cell regions. This facilitates irregular deformation of the wiring member 12, compresses the inter-cell distance, and results in a break in the wiring member 12. The result of the study by the present inventors has elucidated a mechanism of occurrence of a break in the wiring member 12, and accordingly revealed the important factor (the rate of stress relaxation of the first encapsulant 15) that contributes to suppression of occurrence of a break in the wiring member 12. That is, when the rate of stress relaxation of the first encapsulant 15 at a temperature of 90° C. is adjusted within a specific range, the compression of the inter-cell distance can be hindered, so that occurrence of a break in the wiring member 12 is significantly suppressed.

Here, the rate of stress relaxation of the first encapsulant 15 denotes an extent to which Young's modulus of the first encapsulant 15 varies with time. Specifically, the rate of stress relaxation of the first encapsulant 15 is represented by a ratio of an initial value of the Young's modulus of the first encapsulant 15 obtained at the time when the temperature of the first encapsulant 15 reaches a predetermined temperature to a value of the Young's modulus of the first encapsulant 15 obtained when a predetermined length of time has elapsed (after a lapse of 500 seconds, in this specification) since reaching the predetermined temperature. The rate of stress relaxation of the first encapsulant 15 at a temperature of 90° C. (hereinafter, referred to as “the rate of stress relaxation (90° C.)”) is determined by applying a constant force from both sides of the first encapsulant 15 along a thickness direction thereof under a condition that the first encapsulant 15 is heated to the temperature of 90° C., and measuring a thickness of the first encapsulant 15 that is changed with time by the constant force. It should be noted that a specific method for determining stress relaxation can be found with reference to description about a compressive stress relaxation text specified in JIS K6263.

The rate of stress relaxation (90° C.) of the first encapsulant 15 is controlled within the range of 0.18-0.52 as described above. Through the control of the rate of stress relaxation (90° C.) within the above-described range, an amount of change in the inter-cell distance resulting from the thermal cycles can be reduced, to thereby significantly suppress occurrence of a break in the wiring member 12. In an aspect of this disclosure, the rate of stress relaxation (90° C.) is preferably in a range of 0.20˜0.46, or more preferably, 0.24˜0.38. Further, a rate of stress relaxation of the first encapsulant 15 at a temperature of 60° C. (hereinafter, referred to as “the rate of stress relaxation (60° C.)”) may be in a range of 0.80 0.82. When the rate of stress relaxation (90° C.) is in the range of 0.18˜0.52 and the rate of stress relaxation (60° C.) is in the range of 0.80˜0.82, the amount of change in the inter-cell distance resulting from the thermal cycles can be further reduced.

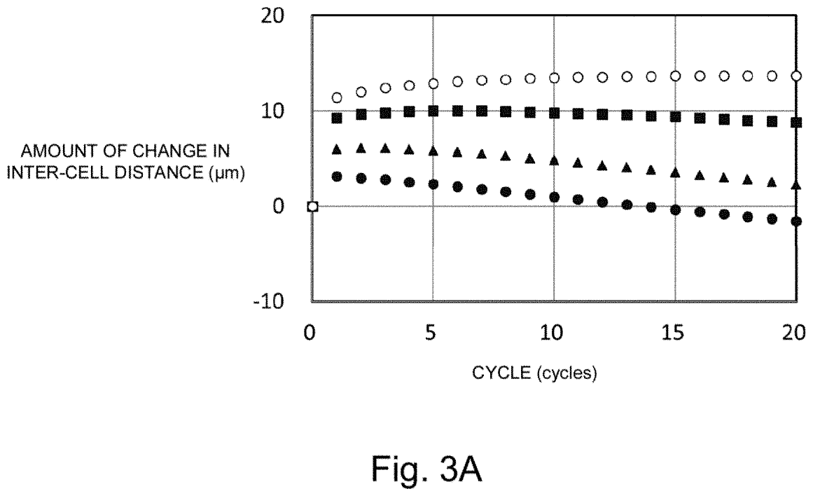

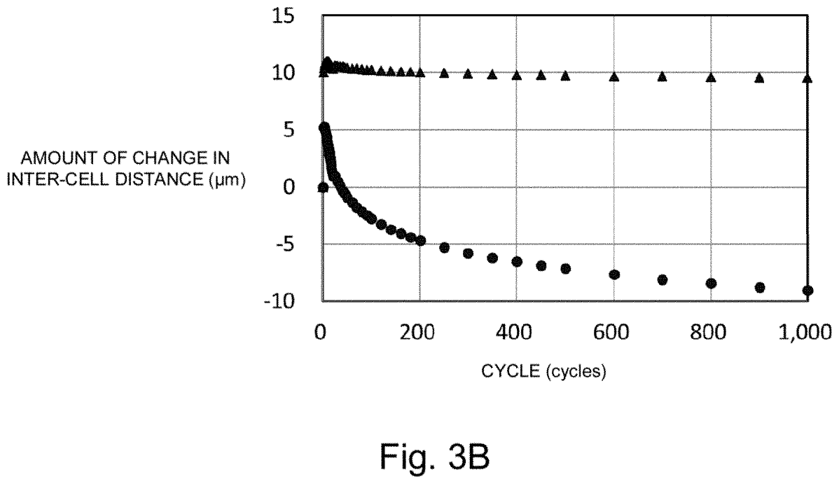

FIGS. 3A and 3B show diagrams representing relationships between the number of thermal cycles and the amount of change in the inter-cell distance identified while changing the rate of stress relaxation of the first encapsulant. The relationships are identified based on a simulation of thermal cycles in a solar cell module according to a finite-element method (FEM). In typical solar cell modules, when the amount of change in the inter-cell distance at the 1,000^{th} cycle becomes greater than ±10 μm, there is a high probability that a break in the wiring member will occur. With this in view, a threshold value of the amount of change in the inter-cell distance at the 1,000^{th} cycle is set to ±10 μm in this simulation.

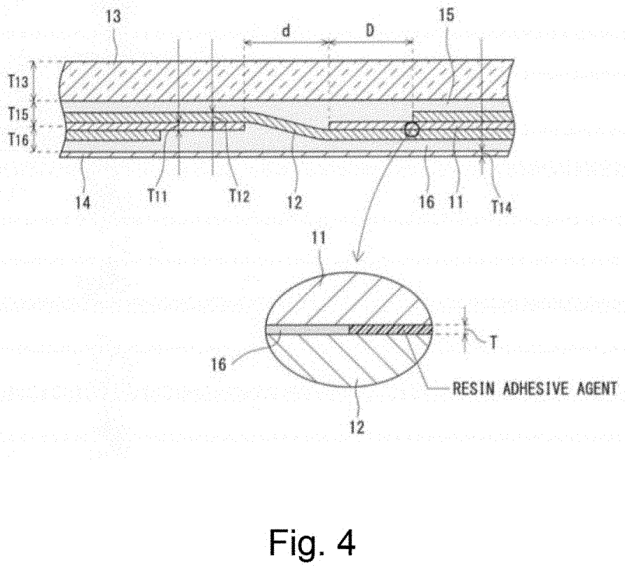

FIG. 4 shows a diagram for explaining a model of the solar cell module employed in this simulation. As shown in FIG. 4, two adjacent solar cells 11 are connected via the wiring member 12 which is attached onto light receiving surfaces and rear surfaces of the two adjacent solar cells 11 by means of a resin adhesive agent. The inter-cell distance (d) is 2 mm before the beginning of the thermal cycles. Three wiring members 12 are arranged on both the light receiving surface and the rear surface of each of the solar cells 11. A width of each of the wiring members 12 is set to 1.2 mm, a width of the resin adhesive agent disposed between each of the wiring members 12 and the solar cell 11 is set to 1.0 mm, and a dimension of the solar cell 11 in a direction along the width of the wiring member 12 is set to 125.3 mm. Further, a distance (D) from an end of the solar cell 11 to an end of the wiring member 12 is set to 2 mm. In a region within the range of the distance (D), space between each solar cell 11 and the wiring member 12 for connecting the two adjacent solar cells 11 is filled with the first encapsulant 15 on the light receiving surface side of the solar cell 11 and with the second encapsulant 16 on the rear surface of the solar cell 11.

Values of Young's modulus, the thermal expansion coefficient, and the thickness of each component are shown in Table 1. Here, the thickness (T15) of the first encapsulant 15 is a dimension measured along the thickness direction of the module from the surface of the first protective base 13 to a thickness center of the solar cell 11. Similarly, the thickness of the second encapsulant 16 is a dimension measured along the thickness direction of the module from the surface of the second protective base 14 to the thickness center of the solar cell 11.

TABLE 1

| | | thermal | | |
|---|---|---|---|---|
| | Young's | expansion | | |
| | modulus | coefficient | Thickness | |
| | (MPa) 25° C. | (1/° C.) | (mm) | |
| the first protective base | 66514 | 0.000010 | 3.2 | (T13) |
| the first encapsulant | 10 | 0.000300 | 0.6 | (T15) |
| the second encapsulant | 10 | 0.000300 | 0.6 | (T16) |
| the resin adhesive agent | 353 | 0.000070 | 0.025 | (T) |
| the solar cell | 190000 | 0.000003 | 0.15 | (T11) |
| the wiring member | 123000 | 0.000017 | 0.22 | (T12) |
| the second protective base | 3000 | 0.000020 | 0.12 | (T14) |

Analysis software and thermal cycle conditions employed in this simulation are as follows:
Analysis Software: FEM Analyzer Software, ABAQUS (manufactured by DASSAULT SYSTEMS CO., LTD.)
Thermal Cycle Condition: 20° C.˜90° C.×1,000 cycles
Output: Amount of Change (Δd) in inter-Cell Distance (d)
Rate of stress Relaxation (90° C.) of First Encapsulant: varied from 0.1099 to 0.8509
Rate of stress Relaxation (90° C.) of Second Encapsulant: 0.8509

The thermal cycle condition is defined to reflect a difference in temperature of the module between daytime and morning time during the summer months in desert climates.

Symbols ●, ▴, ▪, and ∘ indicated in FIG. 3A represent results of the simulation of thermal cycles obtained for the rates of stress relaxation (90° C.) of the first encapsulant 15 which are set to 0.1099, 0.2174, 0.4301, and 0.8509 respectively. Symbols ● and ▴ indicated in FIG. 3B represent results of the simulation of thermal cycles obtained for the rates of stress relaxation (90° C.) of the first encapsulant 15 which are set to 0.1833 and 0.5101, respectively. As shown in FIGS. 3.A and 3B, when the rate of stress relaxation (90° C.) is within a range of 0.1833˜0.5101, the amount of change (Δd) in the inter-cell distance at the 1,000^{th} cycle can be reduced to a value equal to or lower than ±10 μm. In this case, the occurrence of a break in the wiring member 12 can be significantly suppressed. On the other hand, when the rate of stress relaxation (90° C.) is lower than 0.18 or greater than 0.52, the amount of change (Δd) in the inter-cell distance at the 1,000^{th} cycle cannot be reduced to the value equal to or lower than ±10 μm, which raises the possibility that a repetition of thermal cycles will cause a break in the wiring line 12.

As can be understood from the above simulation results, the rate of stress relaxation of the first encapsulant 15 is an important index for reducing the amount of change (Δd) in the inter-cell distance in order to prevent a break in the wiring member, in an attempt to build the solar cell module 10 having a superior tolerance to the thermal cycles. In view of preventing a break in the wiring member, the rate of stress relaxation of the first encapsulant 15 plays an extremely important role, while there are other factors that also play an important role. The factors are suitable ranges of values of Young's modulus, the thermal expansion coefficient, the thickness, and other properties of the first encapsulant 15 as well as values of physical properties of components other than the first encapsulant 15. Among the above values, Young's nodulus of the first encapsulant 15 is particularly important as well as the rate of stress relaxation of the first encapsulant 15.

In an aspect of this disclosure, the Young's modulus of the first encapsulant 15 is preferably in a range of 5 MPa˜100 MPa, more preferably, 10 MPa˜70 MPa, and particularly preferably, 14 MPa˜54 MPa. When the Young's modulus of the first encapsulant 15 is controlled within these ranges, the change in the inter-cell distance resulting from the thermal cycles is mitigated, so that the occurrence of a break in the wiring member 12 can be significantly suppressed. It is therefore desirable for the first encapsulant 15 to have the rate of stress relaxation (90° C.) in the range of 0.18˜0.52 and Young's modulus in the range of 14 MPa˜54 MPa.

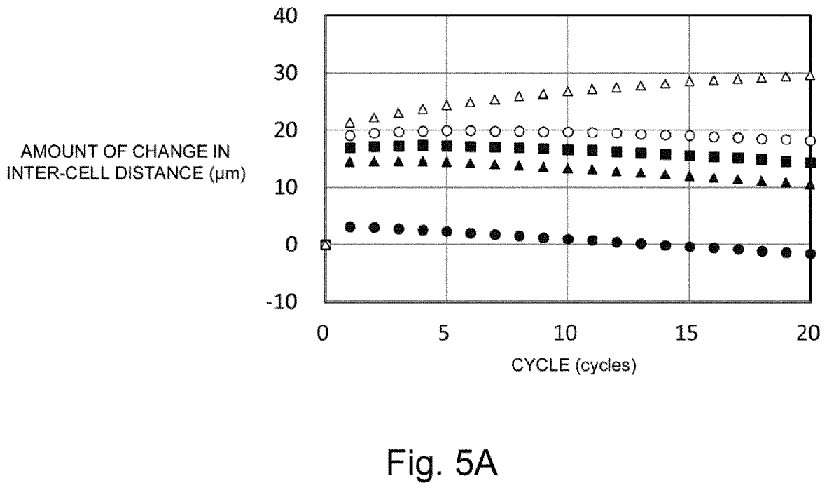

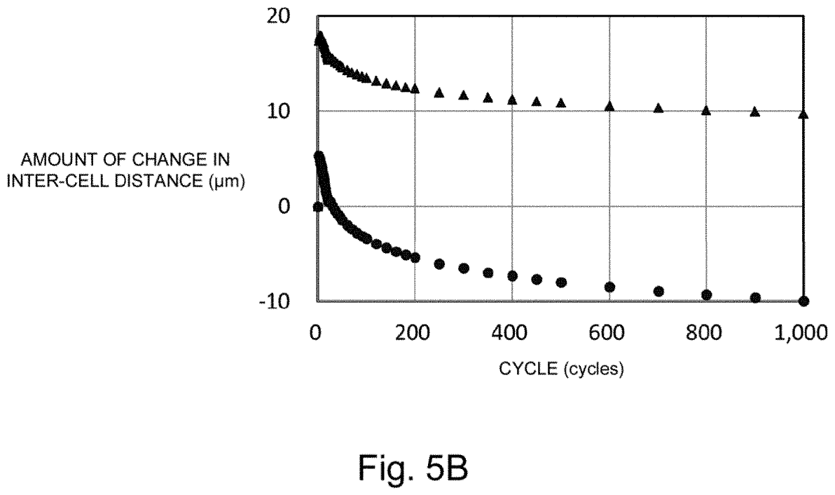

FIGS. 5A and 5B are diagrams representing relationships between the number of thermal cycles and the amount of change (Δd) in the inter-cell distance identified while changing Young's modulus of the first encapsulant 15. The relationships are identified based on a simulation of thermal cycles in the solar cell module 10 according to the finite-element method (FEM). This simulation is performed under the same conditions as those for the previous simulation, other than variables which are changed from the rate of stress relaxation to Young's modulus. Here, the rate of stress relaxation (90° C.) of the first encapsulant is set to 0.1099.

Symbols ●, ▴, ▪, ∘, and A indicated in FIG. 5A represent results of the simulation of thermal cycles obtained with respect to Young's modulus (25° C.) of the first encapsulant 15 that is set to 10 MPa, 37.5 MPa, 50 MPa, 67 MPa, and 300 MPa, respectively. Symbols ● and ▴ indicated in FIG. 5B represent results of the simulation of thermal cycles obtained with respect to Young's modulus (25° C.) which is set to 14 MPa and 54 MPa, respectively. As shown in FIGS. 5A and 5B, when Young's modulus (25° C.) is in the range of 14 MPa˜54 MPa, the amount of change (Δd) in the inter-cell distance at the 1,000^{th} cycle can be reduced to the value equal to or lower than ±10 μm. Accordingly, the occurrence of a break in the wiring member 12 can be significantly suppressed.

Meanwhile, the thermal expansion coefficient of the first encapsulant 15 is preferably in a range of 100 ppm/° C. 500 ppm/° C., or more preferably, 200 ppm/° C.˜400 ppm/° C. The thickness of the first encapsulant 15 is preferably in a range of 0.1 mm˜2 rum, more preferably, 0.2 mm ˜1 mm, or particularly preferably, 0.3 mm˜0.8 mm. Suitable physical properties of the first encapsulant 15 are as follows:
Rate of Stress Relaxation (90° C.): 0.18˜0.52
Rate of Stress Relaxation (60° C.): 0.80˜0.82
Young's Modulus (25° C.): 14 MPa˜54 MPa
Thermal Expansion Coefficient: 200 ppm/° C.˜400 ppm/° C.
Thickness: 0.3 mm˜0.8 mm

The resin constituting the first encapsulant 15 is not specifically limited to any resin as long as the resin satisfies the above-described physical properties. However, in light of retarding deterioration in performance caused by moisture, a resin containing a polyolefin may be preferably used for the first encapsulant 15. The polyolefin is obtained by polymerizing at least one monomer selected from a olefins of carbon number 2˜20, for example. The polyolefin is predominantly composed of a random or block copolymer of ethylene and other a olefins, or a random or block copolymer of propylene and other a olefins, and may preferably include a crosslinking component.

The degree of crosslinking of the first encapsulant 15 can be evaluated by means of a gel fraction. As the gel fraction increases, a crosslinking density of a resin tends to become higher. The gel fraction of the first encapsulant 15 is preferably in a range of 15%˜90%, or more preferably, 25%˜80% The gel fraction (the degree of crosslinking) can be adjusted by appropriately selecting a type of a crosslinking agent, an amount of the crosslinking agent to be added, a below-described heating condition, and the like. The gel fraction of the first encapsulant 16 is, for example, in a range of 20%˜80%.

A gel fraction of an encapsulant is measured with a method described below. Firstly, 1 g of a resin to be measured is prepared, and immersed in 100 ml of a xylene at a temperature of 120° C. for 24 hours. Secondly, a residue within the xylene is extracted and dried at a temperature of 80° C. for 16 hours. Then, the mass of the dried residue is measured. The gel fraction (%) is determined by the following Expression (1).

Gel Fraction (%)=(Mass of Residue)/(Mass of Resin before Immersion) Expression (1)

The first encapsulant 15 may be composed of a combination of a polyolefin and other resins. The other resins may include, for example, polyester, polyurethane, polyacrylonitrile, an epoxy resin, an acrylic resin, and the ethylene/vinyl acetate (EVA) copolymer which has been described as a suitable material for the second encapsulant 16. A polyolefin, the content of which is, for example, 25 wt %˜75 wt % of a total weight of the resin constituting the first encapsulant 15, is formulated so as to satisfy the above described conditions, such as the rate of stress relaxation (90° C.).

The first encapsulant 15 is preferably composed of the resin containing the polyolefin as the principal component. In a case where the polyolefin is mixed with another resin, the polyolefin content is preferably 50 wt % or greater, more preferably, 60 wt % or greater, or particularly preferably, 70 wt % or greater. The first encapsulant 15 may be composed of a resin obtained by mixing a polyolefin, which contains 70 mol % of a constituent unit derived from a propylene, and the EVA at a weight ratio of 75 to 25. The first encapsulant 15 may include a compatibilizer, a surfactant, and other materials in order to enhance mixability of two or more resins.

The physical properties of the second encapsulant 16 have a weaker influence on changes in the inter-cell distance resulting from the thermal cycles than influences of the physical properties of the first encapsulant 15. However, there are preferable ranges of the physical properties of the second encapsulant 16, including the rate of stress relaxation and Young's modulus. The rate of stress relaxation (90° C.) of the second encapsulant 16 is preferably in a range of 0.25˜0.90, or more preferably, 0.40˜0.85. Young's modulus (25° C.) of the second encapsulant 16 is preferably in a range of 5 MPa˜50 MPa, or more preferably, 8 MPa˜20 MPa. The thermal expansion coefficient of the second encapsulant 16 is preferably in a range of 100 ppm/° C.˜500 ppm/° C., or more preferably, 200 ppm/° C.˜400 ppm/° C. The thickness of the second encapsulant 16 is, as in the case of the first encapsulant 15, preferably in the range of 0.1 mm˜2 mm, more preferably, in the range of 0.2 mm˜1 mm, or particularly preferably, in the range of 0.3 mm 0.8 mm. The resin constituting the second encapsulant 16 is not limited to a specific resin, while the EVA may be preferably used for the second encapsulant 16.

The first encapsulant 15 and the second encapsulant 16 may contain a variety of additives. The additives may include, for example, an antioxidant, an ultraviolet absorber, a weatherability imparting agent, a coupling agent, a tackifier, a wavelength conversion material, etc. The coupling agent is contained at least in the first encapsulant 15. The coupling agent may include a silane coupling agent, a titanate based coupling agent, an aluminate based coupling agent, and the like. The second encapsulant 16 may be added with a pigment such as a titanium oxide.

For the first protective base 13, the translucent glass base is used as described above. The first protective base 13 is a rigid component whose stiffness is highest among those of the components of the solar cell module 10, and thus has a great influence on a distribution of stress in the first encapsulant 15 during the thermal cycles. While there is no specific limitation to the thickness of the first protective base 13, the thickness is preferably in a range of 0.5 mm˜10 mm, or more preferably, 1 mm˜5 min in consideration of impact resistance, a reduced weight, light transmittance, and other properties. The first protective base 13 is the thickest component among the components of the solar cell module 10.

The second protective base 14 may be formed using the glass base as in the case of the first protective base 13, while a resin film is preferably used for the second protective base 14 in view of reducing the weight thereof. The resin film is formed of at least one of resins selected from a group of, for example, a cyclic polyolefin, a polycarbonate (PC), polymethyl methacrylate (PMMA), polyether ether ketone (PEEK), polystyrene (PS), polyethylene terephthalate (PET), and polyethylene naphthalate (PEN). Alternatively, the second protective base 14 may be composed of a fiber reinforced plastic (FRP).

Young's modulus, a thickness, and a liner expansion coefficient of the second protective base 14 contribute to changes in the inter-cell distance resulting from the thermal cycles, and may have an effect on occurrence of a break in the wiring member 12. Therefore, it is desirable that Young's modulus and other properties of the second protective base 14 be controlled in below-described specific ranges. The thickness of the second protective base 14 is preferably in a range of 0.05 mm˜0.5 mm, or more preferably, 0.1 mm˜0.3 mm. The occurrence of a break in the wiring member 12 can be significantly suppressed by controlling the physical properties of the second protective base 14.

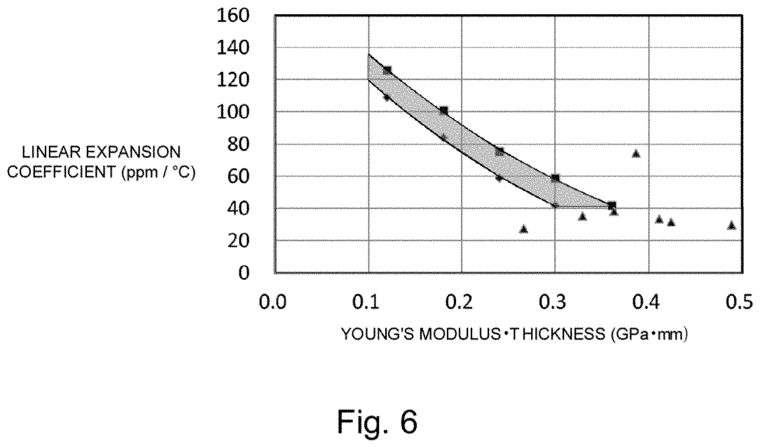

FIG. 6 shows preferable ranges of Young's modulus and the linear expansion coefficient of the second protective base 14. The ranges are determined though the above-described simulation of thermal cycles, taking Young's modulus and the linear expansion coefficient of the second protective base 14 as variables. As shown in FIG. 6, the linear expansion coefficient of the second protective base 14 is preferably equal to or greater than 40 ppm/° C. and a value of (Young's modulus)×(thickness) of the second protective base 14 is preferably equal to or greater than 0.1 GPa˜mm. For the linear expansion coefficient, a lower limit is set to a value (α1) obtained by the following Equation 1 and an upper limit is set to a value (α2) obtained by the following Equation 2.

α1 (ppm/° C.)=583×E²−623×E+176 Equation 1:

α2 (ppm/° C.)=500×E²−590×E+190 Equation 2:

In the above equations, reference letter E represents the value (GPa·mm) of (Young's modulus)×(thickness).

The second protective base 14 is composed of, for example, a resin containing PET as a principal component and having Young's modulus and the linear expansion coefficient which are adjusted to lie in the ranges indicated in FIG. 6.

The solar cells 11, the wiring members 12, and the adhesive agent for bonding the solar cells 11 with the wiring members 12 also have a certain degree of effect on occurrence of changes in the inter-cell distance resulting from the thermal cycles. The solar cell 11 has the second highest stiffness after the first protective base 13 among the components of the solar cell module 10, and has a thickness in a range of, for example, 0.1 mm˜0.3 mm. Preferably, three wiring members 12 are mutually parallelly attached via a resin adhesive agent to each of the light receiving surface and the rear surface of the solar cell 11. The thickness of the wiring member 12 is preferably in a range of 0.1 mm 0.5 mm, or more preferably, 0.2 mm˜0.3 mm. The width of the wiring member 12 is preferably in a range of 0.3 mm˜3.0 mm, or more preferably, 0.5 mm˜1.5 mm. The total width of the wiring members 12 preferably contributes 2.0%˜4.5% of the dimension of the solar cell 11 in a direction in which the wiring materials 12 are arranged side by side on the solar cell 11.

It is preferable that the resin adhesive agent for bonding the solar cell 11 with the wiring members 12 is not applied in a predetermined range from the end of the solar cell 11. In other words, the wiring member 12 is preferably not bonded to the light receiving surface or the rear surface of the solar cell 11 in the predetermined range. In one example, the predetermined range is in a range of 1 mm˜3 mm. The wiring member 12 has the bent portion in a region located in the inter-cell space, and also has, in the vicinity of the bent portion, a portion which is not bonded to the light receiving surface or the rear surface of the solar cell 11.

The solar cell module 10 can be manufactured by forming the string 17 of solar cells 11 through lamination using the first protective base 13, the second protective base 14, the first encapsulant 15, and the second encapsulant 16. In a lamination process, the first protective base 13, the first encapsulant 15, the string 17, the second encapsulant 16, and the second protective base 14 are sequentially stacked in that order on a heater. Such a multilayer structure is heated, for example, at a temperature of 150° C.˜165° C. in a vacuum. During the heating, the first encapsulant 15 and the second encapsulant 16 are molten or softened and accordingly adhered onto the string 17 and the corresponding protective base 13 or 14. As a result, the solar cell module 10 having the cross section structure as shown in FIG. 2 is obtained. After the lamination process, a heating process (a curing process) may be performed at the temperature of 150° C.˜165° C. for 20˜40 minutes. Then, a frame, a terminal box, and other components may be attached as needed.

The degree of crosslinking of the first encapsulant 15 and the second encapsulant 16 can be controlled by adjusting conditions, such as the temperatures and the length of time, in the lamination process and the curing process. In general, higher temperatures and longer length of time will increase the degree of crosslinking of the encapsulants. In a process of manufacturing the solar cell module 10, the conditions applied to the lamination process and the curing process may be changed as appropriate, in order to control the rate of stress relaxation (90° C.) of the first encapsulant 15 within a range of 0.18˜0.82.

As has been described above, in the solar cell module 10 having the above-described structure, the change in the inter-cell distance resulting from the thermal cycles can be reduced, to thereby significantly suppress occurrence of a break in the wiring member 12. This achievement is the result of elucidating the mechanism of causing the wiring member 12 to become broken and finding the important factors (in particular, the rate of stress relaxation (90° C.) of the first encapsulant 15) for reducing the amount of change in the inter-cell distance. This means that the present disclosure reveals design guidelines for implementing superior properties capable of resisting thermal cycles.

While the foregoing has described what are considered to be the best mode and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

1. A solar cell module, comprising:
a plurality of solar cells;
a wiring member configured to connect, among the plurality of solar cells, a first solar cell and a second solar cell which are adjacent to each other;
a first protective base disposed on a light receiving surface side of the plurality of solar cells;
a second protective base disposed on a rear surface side of the plurality of solar cells;
a first encapsulant disposed between the first protective base and the plurality of solar cells; and
a second encapsulant disposed between the second protective base and the plurality of solar cells, wherein
the first protective base is a translucent glass base, and
a rate of stress relaxation of the first encapsulant at a temperature of 90° C. is in a range of 0.18˜0.52.

2. The solar cell module according to claim 1, wherein the first encapsulant is composed of a resin comprising a polyolefin.

3. The solar cell module according to claim 1, wherein a gel fraction of the first encapsulant is in a range of 15%˜90%.

4. The solar cell module according to claim 1, wherein Young's modulus of the first encapsulant is in a range of 14 MPa˜54 MPa.

5. The solar cell module according to claim 1, wherein the rate of stress relaxation of the first encapsulant at a temperature of 60° C. is in a range of 0.80˜0.82.

6. A solar cell module, comprising:
a plurality of solar cells;
a wiring member configured to connect, among the plurality of solar cells, a first solar cell and a second solar cell which are adjacent to each other;
a first protective base disposed on a light receiving surface side of the plurality of solar cells;
a second protective base disposed on a rear surface side of the plurality of solar cells;
a first encapsulant disposed between the first protective base and the plurality of solar cells; and
a second encapsulant disposed between the second protective base and the plurality of solar cells, wherein
the first protective base is a translucent glass base, and
Young's modulus of the first encapsulant is in a range of 14 MPa˜54 MPa.

7. The solar cell module according to claim 1, wherein:
a value of (Young's modulus) (thickness) of the second protective base is equal to or greater than 0.1 GPa·mm;
a linear expansion coefficient of the second protective base is equal to or greater than 40 ppm/° C., and is also confined within a range from a lower limit which is set to a value (α1) determined by Equation 1 to an upper limit which is set to a value (α2) determined by Equation 2,
α1 (ppm/° C.)=583×E²−623×E+176 Equation 1:
α2 (ppm/° C.)=500×E²−590×E+190 Equation 2:
where reference letter E represents the value (GPa·mm) of (Young's modulus)×(thickness) of the second protective base.

8. A solar cell module, comprising:
a plurality of solar cells;
a wiring member configured to connect, among the plurality of solar cells, a first solar cell and a second solar cell which are adjacent to each other;
a first protective base disposed on a light receiving surface side of the plurality of solar cells;
a second protective base disposed on a rear surface side of the plurality of solar cells;
a first encapsulant between the first protective base and the plurality of solar cells; and
a second encapsulant disposed between the second protective base and the plurality solar cells, wherein
the first protective base is a translucent glass base;
a value of (Young's modulus)×(thickness) of the second protective base is equal to or greater than 0.1 GPa·mm; and
a linear expansion coefficient of the second protective base is equal to or greater than 40 ppm/° C., and is also confined within a range from a lower limit which is set to a value (α1) determined by Equation 1 to an upper limit which is set to a value (α2) determined by Equation
α1 (ppm/° C.)=583×E²−623×E+176 Equation 1:
α2 (ppm/° C.)=500×E²−590×E+190 Equation 2:
where reference letter E represents the value (GPa·mm) of (Young's modulus)×(thickness) of the second protective base.
